(19) United States
(12) Patent Application Publication
(10) Pub. No.: US 2007/0147009 A1
(43) Pub. Date: Jun. 28, 2007

(54) Device for cooling an electrical component and production method thereof

(75) Inventors: Jean-Michel Morelle, Beaugency (FR); Laurent Vivet, Boisy d'arcy (FR)

Correspondence Address: OLIFF & BERRIDGE, PLC, P.O. BOX 19928, ALEXANDRIA, VA, 22320, US

(73) Assignee: Valeo Electronique & Systemes de Liaison, Montigny-le-Bretonneux (FR)

(21) Appl. No.: 10/579,624

(22) PCT Filed: Nov. 16, 2004
(86) PCT No.: PCT/FR04/02923

§ 371 Date: Sep. 29, 2006

(30) Foreign Application Priority Data
Nov. 18, 2003 (FR) 0313497

(51) Int. Cl. H05K 7/20

(52) U.S. Cl. 361/720

(57) ABSTRACT

In a device for cooling an electrical component and to the production method thereof, the inventive device includes a metallic radiator-forming member which is thermally connected to a metallic mass of the component that forms a heat-dissipating mass. The radiator is thermally connected to the dissipating mass by at least one heat sink which is formed by an autogenous weld between one face of the dissipating mass, known as the dissipating face, and one face of the radiator, which are facing one another. The invention can be used to cool electronic components, for example, in power electronic modules.

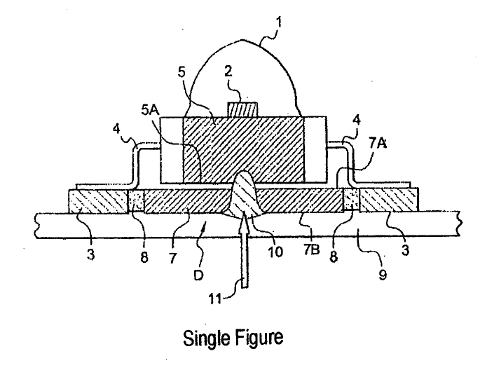

The present invention relates to a device for cooling an exothermic electrical component and a method for producing this device.

The present invention applies more particularly to the cooling of electronic components, for example in power electronic modules.

The prior art already describes a device for cooling an exothermic electrical component of the type comprising a metal member forming a radiator thermally coupled to a metal mass of the component forming a mass for dissipating heat from the component.

Conventionally, the radiator is thermally coupled to the dissipating mass by means of an intermediate mass of a material different to that of the dissipating mass and of the radiator. This added material is commonly an adhesive (polymer) or a solder.

The added material generally undergoes reflow or curing.

In fact, certain electronic components may comprise elements that are incompatible with solder reflow or adhesive curing temperatures. Furthermore, the intermediate mass may have poorer heat conduction properties than one or other of the two materials that it thermally connects.

It is an object of the invention to propose a device for cooling an exothermic electrical component capable of effectively transferring the heat between the dissipating mass and the radiator without damaging the electrical component during the production of such a device.

For this purpose, the invention relates to a device for cooling an exothermic electrical component of the abovementioned type characterized in that the radiator is thermally coupled to the dissipating mass by at least one heat sink formed by an autogenous weld between one face of the dissipating mass, called the dissipating face, and one face of the radiator, opposite each other.

The thermal link between the dissipating mass and the radiator of such a device is created by the melting of the two materials. In consequence, it has heat conduction properties close to those of these two materials. Although the autogenous welding method requires a melting temperature above the temperatures used in conventional methods, the weld is sufficiently localized to avoid damaging the electrical component during the creation of the heat sink.

A cooling device according to the invention may also comprise one or more of the following features:
at least one element among the dissipating mass and the radiator is made from copper;
the component comprises at least one heat source and the heat sink is aligned with this source substantially parallel to a direction perpendicular to the dissipating face;
the heat source comprises a semiconductor;
the area of the dissipating face included in the heat sink corresponds to at least 5% of the area of the dissipating face;
the heat sink also forms a means for fixing the component to the radiator;
the sink also forms a means of electrical conduction between the component and the radiator;
the radiator has a plate shape and is provided with one large face opposite the dissipating mass and one large face, opposite to the preceding face, bearing on a support;
the support is made from a material transparent to a wavelength of a laser welding head;
the radiator is provided with two small opposed faces connected by overmolding of material, preferably of plastic, to two substantially parallel electrically conducting bars;
the device comprises a plurality of heat sinks.

A further subject of the invention is a method for producing the abovementioned device, characterized in that a set of heat sinks is formed by autogenous welding in two steps during each of which one subset of sinks is formed, these two steps being separated by a step of fixing the component to a support separate from the radiator.

A production method according to the invention may also comprise one or more of the following features:
the autogenous welding is carried out using a laser welding head;
the autogenous welding is carried out through the support;
the autogenous welding is carried out using a vacuum electron beam.

The invention will be better understood from a reading of the description below provided exclusively as an example and with reference to the single FIGURE, which shows a cross section of a light emitting diode provided with the cooling device according to the invention.

A light emitting diode 1 comprises a heat source which is a semiconductor 2. The light emitting diode 1 is intended to be cooled using a cooling device according to the invention, denoted by the letter D.

The light emitting diode 1 is provided with conducting lugs 4 which connect it to two substantially parallel electrically conducting bars 3, supplying the light emitting diode 1 with the electric power necessary for its operation. The conducting lugs 4 also enable the mechanical fixing of the light emitting diode 1 to the conducting bars 3.

The semiconductor 2 is supported by a heat dissipating metal mass 5. The dissipating mass 5 comprises one face 5A through which the heat is preferably removed.

The device D comprises a metal plate forming a radiator 7 provided with a large face 7A opposite the face 5A. This radiator 7 comprises two small opposed faces connected to the conducting bars 3 by an overmolded material 8, preferably a plastic, for electrically isolating the radiator 7 from the conducting bars 3.

The radiator 7 and the dissipating mass 5 are preferably made from copper or any other metal, for example a stainless steel, having appropriate heat conducting properties.

The device D is provided with fixing means, not shown in the FIGURE, between, on the one hand, the radiator 7 and the metal bars 3 and, on the other, a support 9. It may be observed that a large face 7B, opposite the face 7A, bears on the support 9. The support 9 is optional.

The device D advantageously comprises at least one heat sink 10 thermally coupling the dissipating mass 5 and the radiator 7. This heat sink 10 is formed by an autogenous weld between the dissipating mass 5 and the radiator 7, more particularly between one face of the dissipating mass 5, called the dissipating face 6, and one face of the radiator 7, opposite each other.

The large face 7A and the dissipating face 5A are separated by the shortest possible distance. This distance is preferably shorter than 50% of the thickness of the radiator 7 (the distance between its faces 7A and 7B), and preferably zero.

In the example in the FIGURE, the heat sink 10 forms a mass inserted between the radiator 7 and the dissipating mass 5.

Advantageously, the heat sink 10 thus formed also serves as means for fixing the diode 1 to the radiator 7 or for electrical conduction between the diode 1 and the radiator 7.

Preferably, the area of the dissipating face 6 included in the heat sink 10 corresponds to at least 5% of the area of this dissipating face 6.

The heat sink 10 is preferably placed so as to be aligned with the heat source substantially parallel to a direction perpendicular to the dissipating face 5A. In other words, the heat sink 10 is placed opposite the heat source, here the semiconductor 2. This arrangement favors dissipation of the heat.

In general, the thermal link between the dissipating mass 5 and the radiator 7 is provided by a set of several heat sinks 10 like the one described previously.

The method for producing the device D with several sinks 10 first consists in conveying the light emitting diode 1 toward the set of conducting bars 3 and the radiator 7, so that the conducting lugs touch the conducting bars 3 and the dissipating face 5A is opposite the large face 7a of the metal plate forming the radiator 7.

A first subset of heat sinks is then formed by autogenous welding of the dissipating mass 5 and the radiator 7.

The conducting lugs 4 are then fixed to a support separate from the radiator 7 preferably to the conducting bars 3, also by autogenous welding. This leaves the time for the heat sinks of the first subset to cool and thereby avoids damaging the light emitting diode 1.

Finally, the remaining heat sinks are formed (second subset of sinks), also by autogenous welding.

The welding is carried out by a vacuum electron beam or by radiation of a laser welding head, shown by the arrow 11. In the latter case, the autogenous welding can be carried out through the support 9, advantageously selected from a material transparent to the laser wavelength.

The invention is not limited to the embodiment described. In particular, the invention may apply to the cooling of any exothermic electrical component, particularly electronic, other than a light emitting diode.

1. A device for cooling an exothermic electrical component, of the type comprising a metal member forming a radiator thermally coupled to a metal mass of the component forming a heat dissipating mass of the component, wherein the radiator is thermally coupled to the dissipating mass by at least one heat sink formed by an autogenous weld between one face of the dissipating mass, called the dissipating face, and one face of the radiator, opposite each other.

2. The device as claimed in claim 1, in which at least one element among the dissipating mass and the radiator is made from copper.

3. The device as claimed in claim 1, in which the component comprises at least one heat source and in which the heat sink is aligned with this source substantially parallel to a direction perpendicular to the dissipating face.

4. The device as claimed in claim 3, in which the heat source comprises a semiconductor.

5. The device as claimed in claim 1, in which the area of the dissipating face included in the heat sink corresponds to at least 5% of the area of the dissipating face.

6. The device as claimed in claim 1, in which the sink also forms a means for fixing the component to the radiator.

7. The device as claimed in claim 1, in which the sink also forms a means of electrical conduction between the component and the radiator.

8. The device as claimed in claim 1, in which the radiator has a plate shape and is provided with one large face opposite the dissipating mass and one large face, opposite to the preceding face, bearing on a support.

9. The device as claimed in claim 8, in which the support is made from a material transparent to a wavelength of a laser welding head.

10. The device as claimed in claim 8, in which the radiator is provided with two small opposed faces connected by overmolding of material, preferably of plastic, to two substantially parallel electrically conducting bars.

11. The device as claimed in claim 1, comprising a plurality of heat sinks.

12. A method for producing a device as claimed in claim 11, wherein a set of heat sinks is formed by autogenous welding in two steps during each of which one subset of sinks is formed, these two steps being separated by a step of fixing the component to a support separate from the radiator.

13. The method as claimed in claim 12, wherein the autogenous welding is carried out using a laser welding head.

14. The method as claimed in claim 13, wherein the device is a device for cooling an exothermic electrical component, of the type comprising a metal member forming a radiator thermally coupled to a metal mass of the component forming a heat dissipating mass of the component, wherein the radiator is thermally coupled to the dissipating mass by at least one heat sink formed by an autogenous weld between one face of the dissipating mass, called the dissipating face, and one face of the radiator, opposite each other, in which the sink also forms a means for fixing the component to the radiator, in which the sink also forms a means of electrical conduction between the component and the radiator, in which the radiator has a plate shape and is provided with one large face opposite the dissipating mass and one large face, opposite to the preceding face, bearing on a support, and in which the support is made from a material transparent to a wavelength of a laser welding head, in which the autogenous welding is carried out through the support.

15. The method as claimed in claim 12, wherein the autogenous welding is carried out using a vacuum electron beam.
